(19) United States
(12) Patent Application Publication
(10) Pub. No.: US 2016/0348885 A1
(43) Pub. Date: Dec. 1, 2016

(54) HEAT DISSIPATING APPARATUS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: BO YANG, Wuhan (CN); XU LI, Wuhan (CN)

(21) Appl. No.: 14/750,629

(22) Filed: Jun. 25, 2015

(30) Foreign Application Priority Data
May 29, 2015 (CN) 201510285915.6

(51) Int. Cl. F21V 29/70; H05K 7/20

(52) U.S. Cl. CPC F21V 29/70; H05K 7/20436; H05K 7/20418

(57) ABSTRACT

A heat dissipating apparatus includes a case used to secure an electronic component and a heat dissipation module secured to the case to dissipate heat generated by the electronic component. The heat dissipation module includes a controller used to set a standard temperature value and a sensor used to be secured to the electronic component. The sensor senses a current temperature value to send to the controller, for allowing the controller to compare the current temperature value with the standard temperature value. When the current temperature value is higher than the standard temperature value, the heating dissipating module is powered on by the controller to dissipate heat generated by the electronic component.

### FIELD

The subject matter herein generally relates to a heat dissipating apparatus.

### BACKGROUND

Many electronic components, such as light-emitting diodes, can generate a great deal of heat, when the electronic components are powered on. A heat sink can be used to dissipate the heat generated by the electronic components.

### BRIEF DESCRIPTION OF THE DRAWINGS

Implementations of the present technology will now be described, by way of example only, with reference to the attached figures.

FIG. 1 is an exploded, isometric view of an embodiment of a heat dissipating apparatus.

FIG. 2 is similar to FIG. 1, but viewed from a different angle.

FIG. 3 is a partially assembled view of the heat dissipating apparatus of FIG. 1, where a reflecting plate is not on a base.

FIG. 4 is a partially assembled view of the heat dissipating apparatus of FIG. 2, where a heat sink is not on the base.

FIG. 5 is an assembled view of the heat dissipating apparatus of FIG. 1.

FIG. 6 is an assembled view of the heat dissipating apparatus of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The present disclosure is described in relation to a heat dissipating apparatus. The heat dissipating apparatus includes a case used to secure an electronic component and a heat dissipation module secured to the case to dissipate heat generated by the electronic component. The heat dissipation module includes a controller used to set a standard temperature value and a sensor used to be secured to the electronic component. The sensor senses a current temperature value to send to the controller, for allowing the controller to compare the current temperature value with the standard temperature value. When the current temperature value is higher than the standard temperature value, the heating dissipating module is powered on by the controller to dissipate heat generated by the electronic component.

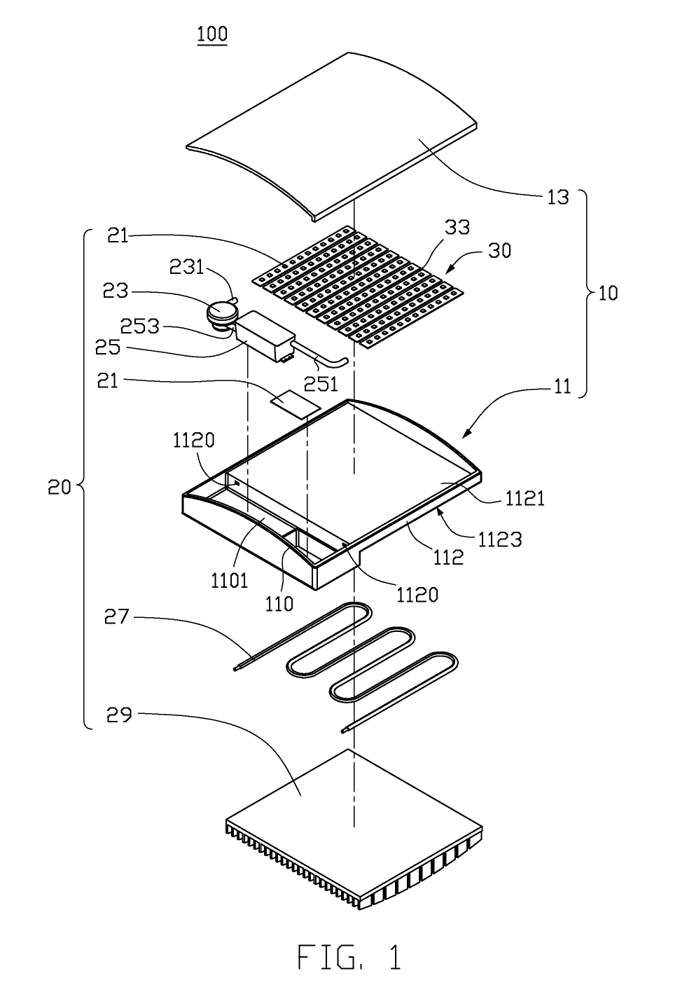

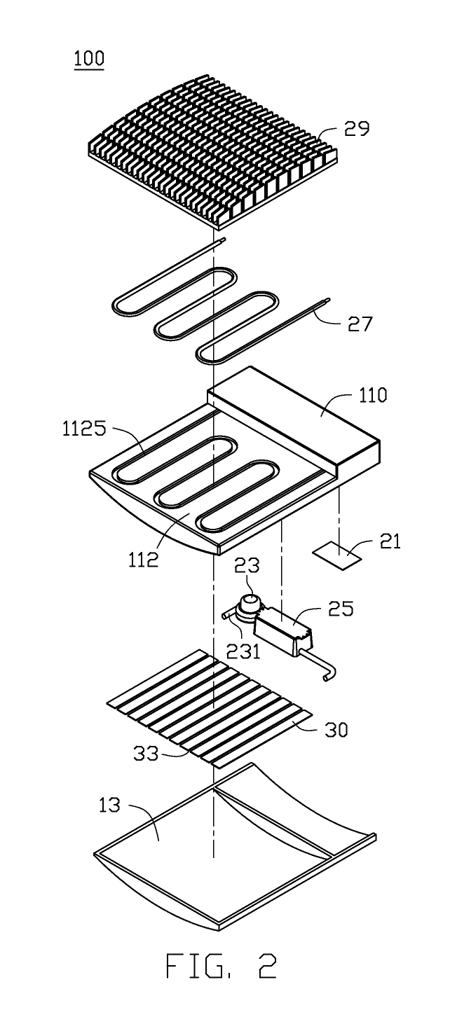

FIGS. 1 and 2 illustrate an embodiment of a heat dissipating apparatus 100. The heat dissipating apparatus 100 can include a case 10 and a heat dissipation module 20 secured to the case 10. The heat dissipating apparatus 100 can be used to dissipate heat generated by electronic components 30. In at least one embodiment, the electronic components 30 can be a plurality of light-emitting diodes arranged in lines and defining a passage 33 between each two adjacent light-emitting diodes.

The case 10 can include a base 11 and a reflecting plate 13 configured to be secured to the base 11. The base 11 can include a receiving portion 110 and a securing portion 112 coupled to the receiving portion 110. A receiving space 1101 is defined in the receiving portion 110. Two through holes 1120 are defined in the securing portion 112. The securing portion 112 further includes a top surface 1121 and a bottom surface 1123 opposite to the top surface 1121. The top surface 1121 is configured to secure the electronic components 30, and a clipping slot 1125 is defined in the bottom surface 1123.

The heat dissipation module 20 can include a controller 21, a plurality of sensors 22, a pump 23, a reservoir 25 configured to store water, a heat dissipating pipe 27, and a heat sink 29. The controller 21 can set a standard temperature value. The plurality of sensors 22 are evenly arranged with the electronic components 30 and configured to detect a current temperature value to send to the controller 21, for comparison of the current temperature value with the standard temperature value. When the current temperature value is higher than the standard temperature value, the controller 21 can start the pump 23, and the water can flow out of the reservoir 25 via a first coupling pipe 251, flow through the heat dissipating pipe 27 and a pump coupling pipe 231, and flow back to the reservoir 25 via a second coupling pipe 253. The heat dissipating pipe 27 can be arranged in the clipping slot 1125, and the opposite ends of the heat dissipating pipe 27 can extend through the through holes 1120 to couple to the first coupling pipe 251 and the pump coupling pipe 231. In at least one embodiment, the first coupling pipe 251, the second coupling pipe 253, and the pump coupling pipe 231 are plastic pipes, and the heat dissipating pipe 27 is a copper pipe.

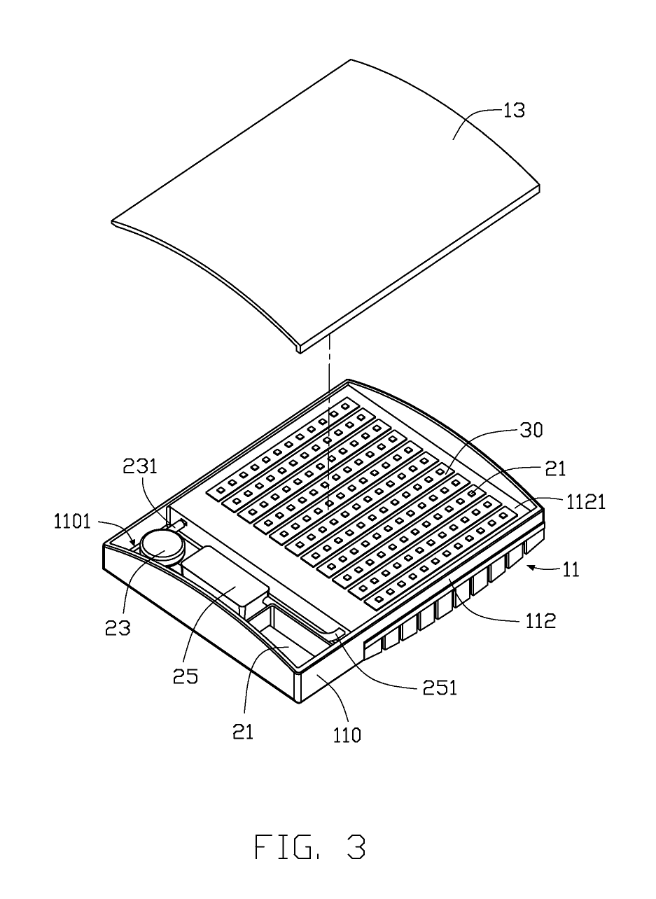

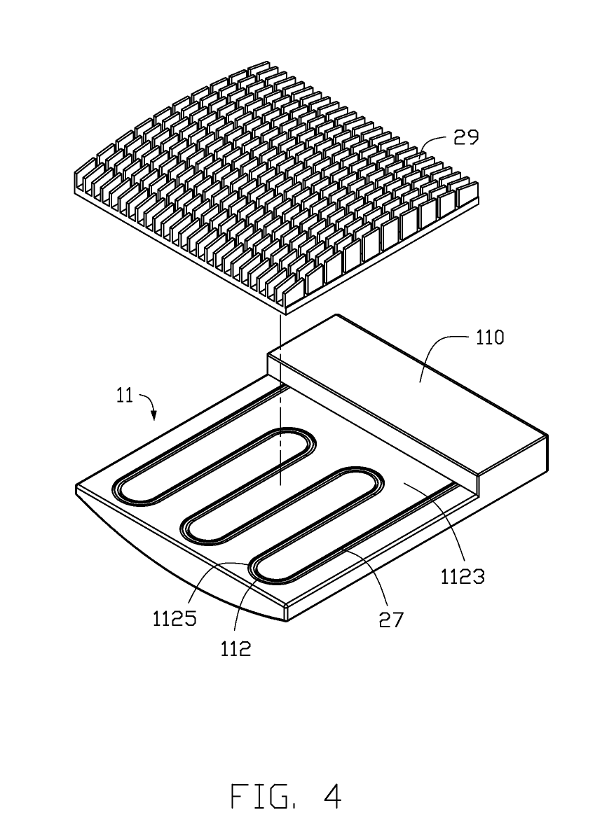

FIGS. 3, and 4 illustrate an assembled view of heat dissipating apparatus 100. In assembly, the heat dissipating pipe 27 is engaged in the clipping slot 1125, and the heat sink 29 is secured to the bottom surface 1123, for allowing the heat dissipating pipe 27 to be located on the bottom portion of the heat sink 29. The opposite ends of the heat dissipating pipe 27 extend through the through holes 1120 to couple to the first coupling pipe 251 and the pump coupling pipe 231. The controller 21, the pump 23, and the reservoir 25 are located in the receiving space 1101. The electronic components 30 are secured to the top surface 1121, and the reflecting plate 13 is secured to the base 11. Thus, the heat dissipating apparatus 100 can be assembled.

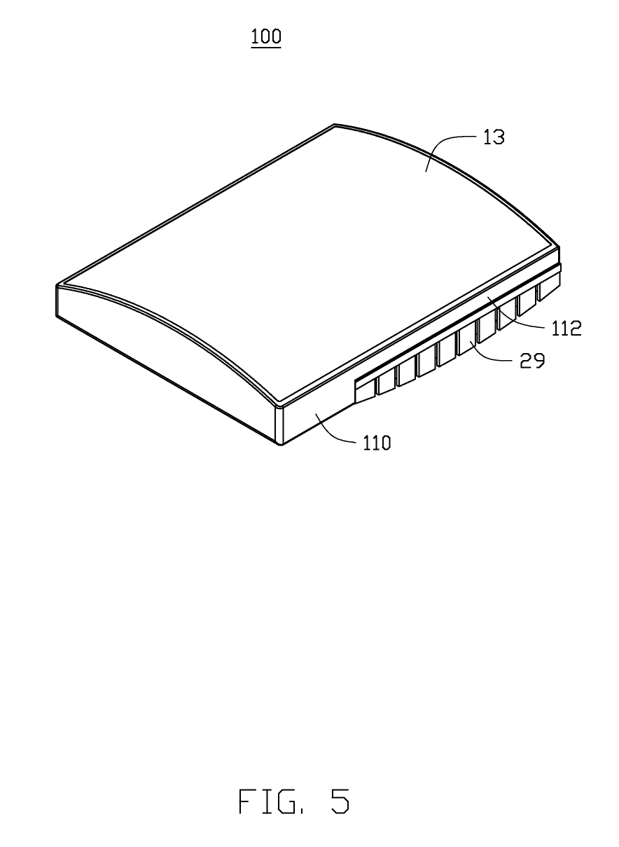

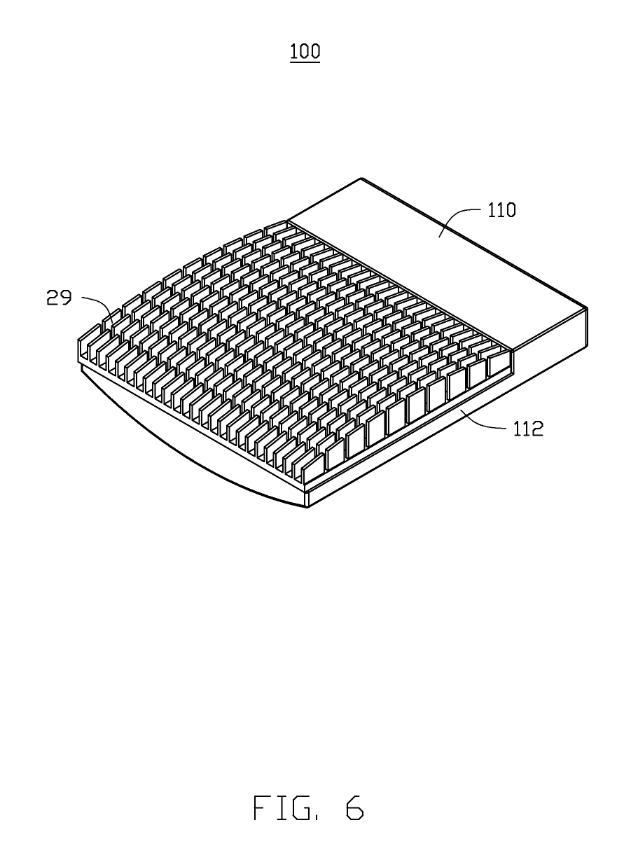

FIGS. 5 and 6 illustrate when the heat dissipating apparatus 100 being used, heat is generated by the electronic components 30, and the heat can be absorbed by the heat sink 29. Simultaneously, the sensors 22 detect the current temperature value to send to the controller 21, for allowing the controller 21 to compare the current temperature value with the standard temperature value. When the current temperature value is higher than the standard temperature value, the controller 21 starts the pump 23 and the water is pumped out of the reservoir 25 via the first coupling pipe 251, flowing through the heat dissipating pipe 27 and the pump coupling pipe 231, and flows back to the reservoir 25 via the second coupling pipe 253. Therefore, the heat generated by the electronic components 30 can be dissipated by the heat dissipating apparatus 100.

The embodiments shown and described above are only examples. Many details are often found in the art such as the other features of a connector plug. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A heat dissipating apparatus comprising:
a case configured to secure an electronic component; and
a heat dissipation module secured to the case and configured to dissipate heat generated by the electronic component, the heat dissipation module comprising:
a controller configured to set a standard temperature value; and
a sensor configured to be secured to the electronic component, the sensor configured to sense a current temperature value to send to the controller, and the controller is configured to compare the current temperature value with the standard temperature value;
wherein the controller is configured such that when the current temperature value exceeds the standard temperature value, the heat dissipation module is powered on by the controller to dissipate heat generated by the electronic component.

2. The heat dissipating apparatus of claim 1, wherein the heat dissipation module further comprises a reservoir, a pump and a heat dissipating pipe coupled to the pump and the reservoir, the heat dissipating pipe is configured to be located on the electronic component, the pump is controllable by the controller to move water in the reservoir out of the reservoir to flow through the heat dissipating pipe.

3. The heat dissipating apparatus of claim 2, wherein the case comprises a base, the base comprises a receiving portion and a securing portion coupled to the receiving portion, the reservoir and the pump are received in the receiving portion, and the heat dissipating pipe is secured to the securing portion.

4. The heat dissipating apparatus of claim 3, wherein the case further comprises a reflecting plate, and the reflecting plate is secured to the base.

5. The heat dissipating apparatus of claim 3, wherein a receiving space is defined in the receiving portion, two through holes are defined in the securing portion and communicate with the receiving space, and opposite ends of the heat dissipating pipe extend through the two through hole to be secured to the securing portion.

6. The heat dissipating apparatus of claim 5, wherein the securing portion comprises a bottom surface, a clipping slot is defined in the bottom surface, and the heat dissipating pipe is engaged in the clipping slot.

7. The heat dissipating apparatus of claim 6, wherein the securing portion further comprises a top surface opposite to the bottom surface, and the top surface is configured to secure the electronic component.

8. The heat dissipating apparatus of claim 6, wherein the heat dissipation module further comprises a heat sink, and the heat sink is located above the heat dissipating pipe and is secured to the bottom surface.

9. The heat dissipating apparatus of claim 1, wherein the electronic component is a light emitting diode.

10. A heat dissipating apparatus comprising:
a case configured to secure an electronic component; and
a heat dissipation module secured to the case and configured to dissipate heat generated by the electronic component, the heat dissipation module comprising:
a heat dissipating pipe configured to be located on the electronic component;
a pump coupled to a first end of the heat dissipating pie via a pump coupling pipe;
a reservoir configured to store water, coupled to a second end of the heat dissipating pipe via a first coupling pipe, and coupled to the pump via a second opposite coupling pipe;
a controller coupled to the pump and configured to set a standard temperature value; and
a sensor configured to be secured to the electronic component, the sensor configured to sense a current temperature value to send to the controller, and the controller configured to compare the current temperature value with the standard temperature value;
wherein the controller is configured such that when the current temperature value exceeds the standard temperature value, the pump is controlled by the controller to move water in the reservoir out of the reservoir to flow through the heat dissipating pipe.

11. The heat dissipating apparatus of claim 10, wherein the case comprises a base, the base comprises a receiving portion and a securing portion coupled to the receiving portion, the reservoir and the pump are received in the receiving portion, and the heat dissipating pipe is secured to the securing portion.

12. The heat dissipating apparatus of claim 11, wherein the case further comprises a reflecting plate, and the reflecting plate is secured to the base.

13. The heat dissipating apparatus of claim 11, wherein a receiving space is defined in the receiving portion, two through holes are defined in the securing portion and communicate with the receiving space, and opposite ends of the heat dissipating pipe extend through the two through hole to be secured to the securing portion.

14. The heat dissipating apparatus of claim 13, wherein the securing portion comprises a bottom surface, a clipping slot is defined in the bottom surface, and the heat dissipating pipe is engaged in the clipping slot.

15. The heat dissipating apparatus of claim 14, wherein the securing portion further comprises a top surface opposite to the bottom surface, and the top surface is configured to secure the electronic component.

16. The heat dissipating apparatus of claim 14, wherein the heat dissipation module further comprises a heat sink, and the heat sink is located above the heat dissipating pipe and is secured to the bottom surface.

17. The heat dissipating apparatus of claim 10, wherein the electronic component is a light emitting diode.
